(19) United States
(12) Patent Application Publication
(10) Pub. No.: US 2026/0314317 A1
(43) Pub. Date: Oct. 8, 2026

(54) OPERATION METHOD AND DEVICE FOR CLEANING FOUP

(71) Applicant: ASIA NEO TECH INDUSTRIAL CO., LTD., Taoyuan City (TW)

(72) Inventor: PU-CHANG YEH, Taoyuan City (TW)

(21) Appl. No.: 19/568,589

(22) Filed: Mar. 16, 2026

Related U.S. Application Data
(60) Provisional application No. 63/793,179, filed on Apr. 23, 2025.

(30) Foreign Application Priority Data
Apr. 8, 2025 (TW) 114113248

(51) Int. Cl. H10P 72/30; H10P 72/00

(52) U.S. Cl. CPC H10P 72/3406; H10P 72/0408; H10P 72/0411; H10P 72/0616; H10P 72/3402

(57) ABSTRACT

An operating method and device for cleaning a FOUP, applied in a cleaning area station for the FOUP, comprising performing unlocking and/or defect inspection of the FOUP at a load port. The unlocking includes unlocking a door from a shell, and the defect inspection includes detecting defective shells or doors with deformed shapes or structures. The present invention also includes using a gripper having two clamping devices to grip and transport the unlocked and/or defect-inspected shell and door to the cleaning area station for cleaning, and subsequently locking the cleaned FOUP at the load port, thereby shortening the cleaning operation time for the FOUP shell and door, and eliminating the cleaning time occupied by defective products.

### BACKGROUND OF INVENTION

### 1. Field of the Invention

The present invention relates generally to a Front Opening Unified Pod (FOUP), and more particularly to an operation method and device for cleaning FOUP.

### 2. Description of Related Art

A FOUP is composed of a shell having a chamber and a door coupled to the shell in a locking manner. The FOUP can accommodate objects such as wafers, carriers, or panels within the chamber, facilitating the transport of the FOUP to multiple processing stations by an OHT (Overhead Hoist Transport), thereby enabling the necessary processing of said accommodated objects.

It is also known that, depending on process requirements, the interior of the FOUP often needs to be filled with a gas such as nitrogen to maintain the process quality of the accommodated objects. After a period of use, the FOUP must be cleaned to remove harmful substances accumulated or remaining on the shell and door, thereby maintaining the production yield of said process components during manufacturing. Said harmful substances include airborne particles, volatile organic compounds (VOCs), sulfur dioxide (SO2), amines, acids, ammonia (NH3), and the like.

To this end, a cleaning area station is often added for the FOUP among the multiple processing stations arranged on the production line according to process requirements. Please refer to FIG. 1a, which discloses an embodiment of a cleaning area station 200 specifically configured in the prior art for cleaning said FOUP 10. The FOUP 10 can be automatically placed onto at least one load port 280 of the cleaning area station 200 by means of hoisting and transport by the OHT, thus carrying the FOUP transported by the OHT to enter and exit the cleaning area station 200.

The cleaning area station 200 is typically equipped with a multi-axis robot 270 and, arranged around the robot 270, a plurality of cleaning machines 220, 230, 240 for wet cleaning and vacuum drying purposes, an unlocking station 250, and an inspection station 260. Specifically, the robot 270 is fitted with a gripper 271 (or clamp) capable of gripping the FOUP 10, the shell 11, and the door 12; said unlocking station 250 and said inspection station 260 are respectively located at the ends of said cleaning machines 220, 230, 240. With this configuration, the robot 270 can grip and place the FOUP 10 from the load port 280, and transfer the FOUP 10 to the unlocking station 250 to unlock it into a state where the shell 11 and the door 12 are separated, facilitating the subsequent transfer of the shell 11 and the door 12 one by one to the inspection station 260 for respective defect inspection, thereby rejecting defective shells 11 and doors 12. Subsequently, the robot 270 transfers the accepted shells 11 and doors 12 respectively to the plurality of cleaning machines 220, 230, 240 for cleaning processes including wet cleaning and vacuum drying. Thereafter, the robot 270 transfers the cleaned shell 11 and door 12 back to the unlocking station 250 to be locked together to reassemble the FOUP 10.

However, the above-mentioned prior art practice of separately arranging the unlocking station 250 and the inspection station 260 within said cleaning area station 200 obviously increases the number of stations involved in the cleaning transfer process, which consequently increases the operating time for the robot 270 in transferring the shell 11 and the door 12 during the cleaning process. This will affect the cleaning efficiency of the FOUP.

Further, the current gripper 271 applied in the cleaning area station 200 can generally only grip one of the FOUP 10, the shell 11, or the door 12 at a time. Therefore, the robot 270 must transport the shell 11 and the door 12 of the FOUP separately in multiple trips, frequently moving back and forth between the unlocking station 250 and the plurality of cleaning machines 220, 230, 240. Consequently, the increased handling time reduces the operational efficiency of the cleaning area station.

Please refer to FIG. 1b, which illustrates the state of the shell 11 and the door 12 of the FOUP 10 after being unlocked and separated. The shell 11 has an opening 110, within which a chamber 111 is formed to accommodate a plurality of stored items. On both sides of the chamber 111, there are multiple corresponding guide ribs 112 arranged in rows. The outer wall on one side of the shell 11 is provided with a flange 113 (commonly known as a "mushroom head") for OHT handling. Additionally, multiple screws 114 are fastened to the outer wall of the shell 11, used to secure the plurality of guide ribs 112 arranged in rows inside the opening 110. Further, the inner peripheral surface of the door 12 is provided with a sealing gasket 120 and guide ribs 121 arranged in rows. The function of the sealing gasket 120 is to provide a seal after the door 12 is closed and locked with the shell 11. The row-shaped guide ribs 121 on the door 12 and the row-shaped guide ribs 112 inside the shell 11 are arranged in mutually corresponding layers, surrounding the chamber 111 to guide and hold items such as wafers, carriers, or panels in layers. Additionally, please refer to FIG. 1c, which shows that the bottom of the shell 11 has a pair of exhaust valve ports 13 and a pair of inlet valve ports 14, as well as multiple screw holes 15 for screws to pass through and lock onto the inner wall of the chamber, used for fitting screws to install certain functional components.

However, for the shell 11 and the door 12, after a period of use, the shell 11, the door 12, and their guide ribs 112, 121, may develop defects such as warping, deformation, or breakage. Further, the sealing gasket 120 may also age or become damaged, causing defects in the FOUP 10. Said defects in the shell and the door must be identified and removed from the production line to guarantee the normal functionality of the FOUP.

In order to detect said defects of the FOUP 10 on the production line, prior art has incorporated defect detection technology into the FOUP 10 cleaning process. Further, please refer to FIG. 1a, which discloses that said cleaning processing station 20 is additionally equipped with an inspection station 260, used to detect defective shells 11 and doors 12.

However, in the above-mentioned prior art, the inspection station 260 is located between the unlocking station 250 and the cleaning machines 220, 230, 240. This also increases the number of stations in the cleaning and handling process, thereby affecting the operational time of the robot 270 when handling the shell 11 and door 12 sequentially through unlocking, defect inspection, cleaning, and locking processes. Therefore, it remains unfavorable for improving the cleaning efficiency of FOUPs, and the above issues urgently need improvement.

### SUMMARY OF THE INVENTION

In view of this, the present invention focuses on the operational process of unlocking, transporting, and defect inspection of FOUPs within existing FOUP cleaning area stations, which increases the FOUP cleaning operation time. It proposes improvement strategies, particularly including improving the arrangement positions of the unlocking station and the inspection station, as well as the gripping and transport mode of the gripper (clamp) attached to the robot, thereby shortening the FOUP cleaning operation time.

To this end, a preferred embodiment of the present invention provides an operating method for cleaning FOUPs, applied in a cleaning area station for the FOUP. The cleaning area station includes at least one load port for placing the FOUP, a plurality of cleaning machines for cleaning the FOUP, and a robot for transporting the FOUP between the at least one load port and the plurality of cleaning machines. The at least one load port is provided with an unlocker for unlocking the FOUP into a shell and a door, and for locking the shell and the door together to form the FOUP. The robot has a gripper attached thereto, the gripper having a first clamping device and a second clamping device respectively disposed on two opposite end surfaces thereof. The operating method comprises: unlocking and opening the door on the shell by means of the unlocker on the at least one load port; then, gripping the shell from the at least one load port by means of the first clamping device of the gripper, and gripping the door from the at least one load port by means of the second clamping device of the gripper; enabling the gripper to simultaneously transport the shell and the door from the at least one load port and place them one by one into the plurality of cleaning machines for cleaning; and sequentially gripping the shell and the door cleaned by the plurality of cleaning machines, thereby enabling the gripper to simultaneously transport the shell and the door from the plurality of cleaning machines to the at least one load port, and using the unlocker to assemble the door onto the shell and lock them together to form the cleaned FOUP.

In a further implementation, the unlocker uses one of a swinging motion or a linear motion to open the door on the shell. Furthermore, the robot drives the gripper to reciprocally flip by a specific angle, enabling the first clamping device to grip and release the shell, and the second clamping device to grip and release the door. The two opposite end surfaces of the first clamping device and the second clamping device are parallel and correspond to each other, and the specific angle is 180 degrees. The first clamping device grips a flange on the shell, and the second clamping device grips both side edges of the door.

In a further implementation, at least one photosensitive coupling element is provided around the at least one load port. The operating method further includes, after the unlocker unlocks and opens the door on the shell, and before the gripper grips the shell and the door, inspecting the quality of the shell and the door by means of the at least one photosensitive coupling element at the at least one load port. The shell and the door have a plurality of internal standard features according to product specifications, and the at least one photosensitive coupling element is used to detect a plurality of internal current features of the shell and the door. The operating method further includes comparing differences between the internal current features and the internal standard features to determine defect locations on the shell and the door, and selecting good shells and doors, allowing the gripper to grip and transport the unlocked good shell and good door from the at least one load port to the plurality of cleaning machines for cleaning. Furthermore, the internal standard features are constituted by at least one standard image of an inner end surface of the shell and the door, and the internal current features are respectively constituted by at least one current image of an inner end surface of the shell and the door. The shell and the door also have a plurality of external standard features according to product specifications. The operating method further includes, before unlocking and opening the door on the shell, detecting a plurality of external current features of the shell and the door, and comparing differences between the external current features and the external standard features. Moreover, the photosensitive coupling element detects the external current features and the internal current features using at least one of a fixed method and a moving method. The external standard features are constituted by at least one standard image of an outer end surface of the shell and the door, and the external current features are constituted by at least one current image of an outer end surface of the shell and the door.

In a further implementation, the at least one load port includes at least one input port and at least one output port. The operation of unlocking the FOUP into the shell and the door is performed at the at least one input port, and the operation of locking the shell and the door together to form the FOUP is performed at the at least one output port. At the at least one input port, the door is unlocked from the shell by means of a door opener, and at the at least one output port, the door is locked onto the shell by means of a door closer, and the door closer uses one of a swinging motion or a linear motion to close the door on the shell.

The present invention also provides an operating device for cleaning a FOUP, capable of executing the above operating method. The device is configured in a cleaning area station for the FOUP, used to unlock the FOUP into a shell and a door, transport the shell and the door for cleaning, and lock the cleaned shell and door together to form the FOUP. The cleaning area station includes at least one load port for placing the FOUP, a plurality of cleaning machines for cleaning the FOUP, and a robot for transporting the FOUP between the at least one load port and the plurality of cleaning machines. The at least one load port has a table surface for placing the FOUP. The operating device comprises an unlocker and a gripper. The unlocker is disposed on one side of the at least one load port, adjacent to the table surface. The unlocker has a pair of keys capable of inserting into a pair of locking holes of the door, used to unlock and open the door on the shell, and to lock the shell and the door together to form the FOUP. The gripper is attached to the robot. The gripper has a first clamping device and a second clamping device respectively disposed on two opposite end surfaces thereof. The first clamping device is used for gripping and releasing the shell between the at least one load port and the cleaning stations. The second clamping device is used for gripping and releasing the door between the at least one load port and the cleaning stations. The robot drives the gripper to reciprocally flip by a specific angle, enabling the first clamping device to grip and release the shell, and the second clamping device to grip and release the door.

In a further implementation, the unlocker has a base capable of holding the door. The pair of keys protrudes outward from a base surface of the base. The base has a pivot portion, by which the base is pivotally connected to an end side of the table surface of the at least one load port. This allows the base to insert the pair of keys into the pair of locking holes of the door in a swinging motion, unlocking and opening the door on the shell. Alternatively, the base is slidably assembled to the end side of the table surface of the at least one load port via a linear slide rail. This allows the base to insert the pair of keys into the pair of locking holes of the door in a linear movement, unlocking and opening the door on the shell.

In a further implementation, the operating device further comprises the photosensitive coupling element suspended around the table surface of the at least one load port, used to detect a plurality of current features of the unlocked shell and door at the at least one load port.

In a further implementation, the at least one load port is at least one input port for placing the FOUP. The cleaning area station further includes at least one output port. The output port uses a door closer to lock the door onto the shell to form the FOUP. The door closer is disposed on an end side of a table surface of the output port. The door closer has a pair of keys that insert into a pair of locking holes of the door, used to hold the door and lock the door onto the shell.

Furthermore, the door closer has a base capable of holding the door. The pair of keys protrudes outward from a base surface of the base. The base has a pivot portion, by which the base is pivotally connected to the end side of the table surface of the output port. This allows the base to insert the pair of keys into the pair of locking holes of the door in a swinging motion, holding the door and locking the door onto the shell. Alternatively, the base is slidably assembled to the end side of the table surface of the output port via a linear slide rail. This allows the base to insert the pair of keys into the pair of locking holes of the door in a linear motion, holding the door and locking the door onto the shell.

Implemented in this way, compared to the prior art, since the processes of unlocking the FOUP and inspecting the shell and the door are both performed at the at least one load port, and the gripper can grip, transport, and release the shell and the door in a single operation, unlike the conventional process where unlocking the FOUP and inspecting the shell and the door are performed inside the cleaning area station 200 shown in FIG. 1a, relying on the robot 270 for transport. The present invention thus achieves the following effects:
(1) Reducing the operation time of the robot 270 shown in FIG. 1a during the sequential transport of the shell 11 and door 12 for unlocking, defect inspection, cleaning, and locking processes.
(2) Shells 11 or doors 12 identified as defective through inspection at the inspection station 260 shown in FIG. 1a can be directly removed by an OHT or other automated equipment to eliminate defective products from the line. This prevents the robot 270 inside the cleaning area station 200 from picking up already defective shells 11 or doors 12 for cleaning, thereby improving the cleaning efficiency of good products.

Further benefits and advantages of the present invention will become apparent after a careful reading of the detailed description with appropriate reference to the accompanying drawings.

### BRIEF DESCRIPTION OF THE DRAWINGS

FIG. 1a is a schematic top view of a conventional cleaning area station for FOUPs, illustrating that the cleaning area station is equipped with a robot, cleaning machines, an unlocking station, an inspection station, and load ports.

FIG. 1b is an exploded perspective view of the FOUP shown in FIG. 1a after unlocking, illustrating that the article comprises a shell and a door.

FIG. 1c is a bottom view of the shell shown in FIG. 1b, illustrating that the bottom of the shell is provided with normally closed exhaust valve ports and inlet valve ports.

FIG. 2 is a schematic top view of a FOUP cleaning area station equipped with the operating device of the present invention, illustrating that the cleaning area station is configured with a robot, cleaning machines, and load ports, and the load ports are configured with an unlocker and photosensitive coupling elements constituting the defect inspection device.

FIG. 3 is a first perspective view of the load port shown in FIG. 2, further illustrating the configuration of the unlocker and the photosensitive coupling elements, wherein the unlocker includes a door opener and a door closer.

FIG. 4 is a top view showing another configuration of the unlocker shown in FIG. 3.

FIG. 5 is a perspective view of the gripper attached to the robot shown in FIG. 2, viewed from a first angle, disclosing that one end surface of the gripper is provided with a gripper capable of gripping the flange on the shell.

FIG. 6 is a perspective view of the gripper shown in FIG. 5, viewed from a second angle, disclosing that the other end surface of the gripper is provided with a gripper capable of gripping the opposite side edges of the door.

FIG. 7 is a perspective view of the gripper shown in FIGS. 5 and 6 gripping the shell and the door, disclosing that the gripper can be flipped 180 degrees to grip and release the shell and the door on different end surfaces.

FIG. 8 is a block flow diagram of a preferred embodiment of the operating method of the present invention.

FIG. 9 is a perspective operational view showing the door opener shown in FIG. 3 covering the door, illustrating the door opener swinging to cover the door of the FOUP for unlocking.

FIG. 10 is a perspective operational view showing the door opener shown in FIG. 9 subsequently opening the door, illustrating the door opener holding the door and swinging back to a horizontal position, thereby opening the door on the shell, and allowing multiple photosensitive coupling elements to capture the internal current features and external current features of the shell and the door.

FIG. 11 is another perspective operational view showing the door opener shown in FIG. 10 opening the door, illustrating the door opener holding the door and swinging to a vertical position, thereby opening the door on the shell, and allowing multiple photosensitive coupling elements to capture the internal current features and external current features of the shell and the door.

FIGS. 12(a)-12(g) are operational schematic diagrams of the gripper shown in FIGS. 5 and 6.

FIGS. 13-14 are perspective views of the continuous operation of the door closer shown in FIG. 3 performing door locking.

FIG. 15 is a block flow diagram of another preferred embodiment derived from FIG. 8.

FIG. 16 is a perspective view showing another placement position of the shell in FIG. 11, illustrating the shell rotated 180 degrees, allowing the photosensitive coupling element to capture an image of the outer wall surface on the back, as part of the external current features.

### DETAILED DESCRIPTION OF THE INVENTION

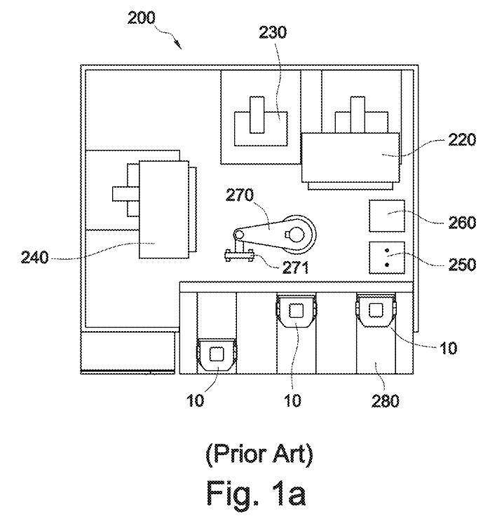

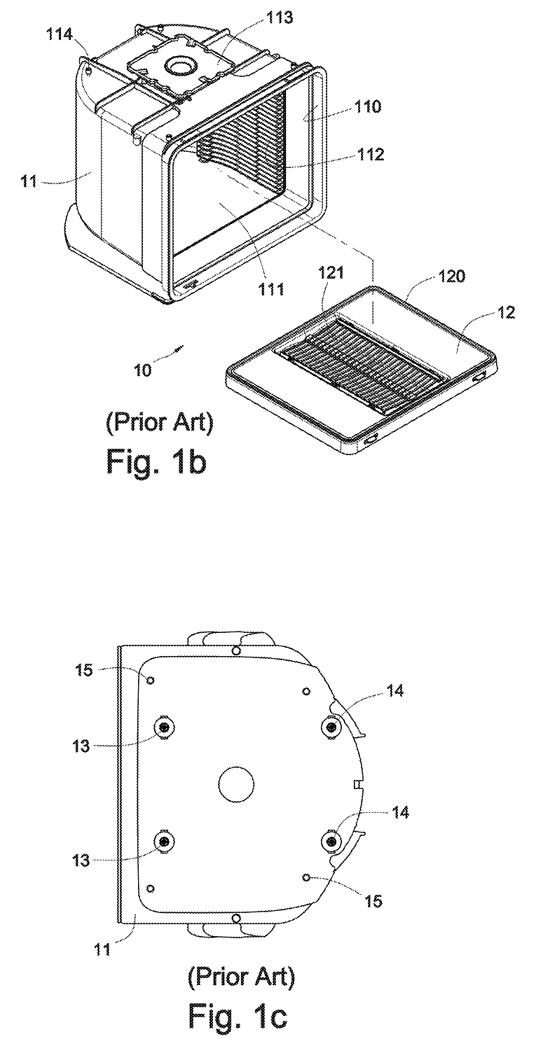

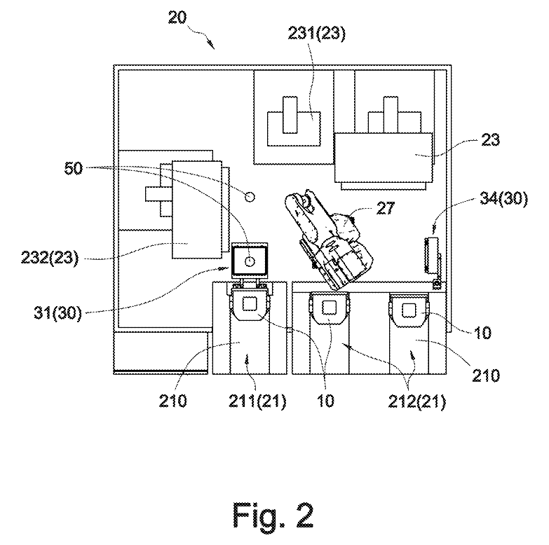

First, please refer to FIG. 2, which discloses an operating device for cleaning the FOUP 10 provided by the present invention. The device is configured in a cleaning area station 20 for the FOUP 10. The cleaning area station 20 is already configured with at least one load port 21 for placing the FOUP 10, a plurality of cleaning machines 23 for cleaning the FOUP 10, and a robot 27 for transporting the FOUP 10 between the at least one load port 31 and the plurality of cleaning machines 23. The load port 21 has a table surface 210, which can first provide a place for the FOUP 10 to be cleaned to be placed, and subsequently provide a place for the cleaned FOUP 10 to be placed. Furthermore, the plurality of cleaning machines 23 can each be equipped with functions such as wet cleaning or vacuum drying for the shell 11 and door 12 of the FOUP 10 shown in FIG. 1b. Moreover, the robot 27 can also be replaced by an automated tool with multi-axis movement capability, allowing multiple or a single load port 31 and the plurality of cleaning machines 23 to be arranged around the robot 27, enabling the robot 27 to transport the shell 11 and door 12 between the load port 21 and the plurality of cleaning machines 23.

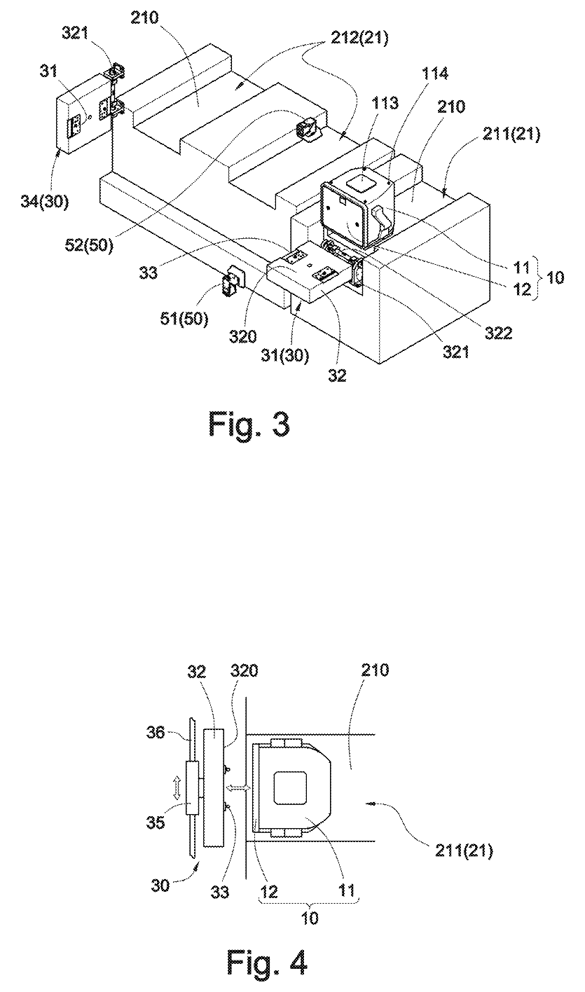

Please refer to FIGS. 2 and 3 together. They jointly disclose that the plurality of load ports 21 in the cleaning area station 20 can be distinguished into at least one input port 211 and one or more output ports 212. The input port 211 is dedicated for an OHT to transport the FOUP 10 to be cleaned here for placement. The output port 212 is dedicated for the robot 27 in the cleaning area station 20 to transport the cleaned FOUP 10 here for placement. The greater the number of input ports 211 and output ports 212, the more they can serve as temporary storage areas for FOUPs 10, avoiding waiting time for the OHT to load and the robot 27 to pick up. In other words, in a possible alternative implementation, only one load port 21 is needed, which provides placement for FOUPs both before and after cleaning. Although this is more time-consuming, it still falls within the applicable technical scope. In other words, the present invention is not limited by the load port 21 being an input port, an output port, or simultaneously serving as input and output, nor by its quantity, and this is clearly stated here.

Based on the above configuration environment of the cleaning area station 20, the operating device provided by the present invention can be installed, including installing an unlocker 30 on at least one load port 21, and attaching a gripper 40 (or clamp) to the robot 27. In addition, the operating device of the present invention can optionally further include at least one photosensitive coupling element 50 (CCD).

As also shown in FIGS. 2 and 3, it further discloses that the unlocker 30 is arranged on an end side of the table surface 210 of the load port 21, used to unlock the FOUP 10 to be cleaned and not yet unlocked, separating it into the shell 11 and door 12 shown in FIG. 1b. Furthermore, the unlocker 30 can also lock the cleaned shell 11 and door 12 together to form the FOUP 10. More specifically, the unlocker 30 has a pair of keys 33 that insert into the pair of locking holes of the door 12, used to unlock the FOUP 10 and open the door 12 on the shell 11.

As shown in FIG. 3, the unlocker 30 has a base 32 capable of holding the door 12. The pair of keys 33 protrudes outward from a base surface 320 of the base 32. When the load port 21 is distinguished into the input port 211 and the output port 212, the unlocker 30 can be distinguished into a door opener 31 installed on the end side of the table surface 210 of the input port 211, and a door closer 34 installed on the end side of the table surface 210 of the output port 212. The door opener 31 at the input port 211 is specifically responsible for unlocking and opening the door 12 on the shell 11. The door closer 34 at the output port 212 has the same structure as the door opener 31 and is specifically responsible for bringing the door 12 together with the shell 11 and locking them to form the FOUP 10.

Furthermore, the unlocker 30 shown in FIG. 3 is implemented in a swinging form. Specifically, the base 32 has a pivot portion 321, and at least one arm portion 322 connecting the pivot portion 321 and the base 32. The base 32 is pivotally connected to the end side of the table surface 210 of the load port 21 via the arm portion 322 and the pivot portion 321, so that the base 32 can insert the pair of keys 33 into the pair of locking holes of the door 12 in a swinging motion, unlocking and opening the door 12 on the shell 11.

Additionally, please refer to FIG. 4, which discloses implementing the unlocker 30 in a rail-sliding form. Specifically, the base 32 can be arranged on a slide carriage 35, which is slidably arranged on a linear slide rail 36. This allows the slide carriage 35 to move the base 32 bi-axially (indicated by double-headed arrows in FIG. 4), positioning it at the end side of the table surface 210 of the load port 21. This enables the base 32 to insert the pair of keys 33 into the pair of locking holes of the door 12 in a bi-axial linear movement manner, unlocking and opening the door 12 on the shell 11. Similar designs for unlocking, opening, and closing the door 12 all fall within the technical scope that can be easily modified and applied by the present invention.

As also shown in FIGS. 2 and 3, it further discloses that at least one photosensitive coupling element 50 can be suspended around the table surface 210 of the load port 21 by means of a connecting rod or a driving element (not shown in the figure) used as a fixed end.This is used to detect a plurality of current features of the shell 11 and the door 12 after the FOUP 10 to be cleaned is unlocked and before it is ready to be cleaned, thereby determining whether the shell 11 and the door 12 to be cleaned have defects (to be detailed later).

FIG. 3 discloses that one or more photosensitive coupling elements 50 can be used, suspended, in at least one fixed or movable manner, around the table surface 210 of the load port 21 to detect the current features. When there are multiple photosensitive coupling elements 50, they may include a first photosensitive coupling element 51 capable of capturing an image corresponding to the position of the opening 110 (see FIG. 1b) of the shell 11, and a second photosensitive coupling element 52 capable of capturing an image corresponding to the outer wall surface of the door 12, or the outer wall surface of the shell 11 and the top position of the shell 11 (including the flange 113), used to detect the current features of the shell 11 and the door 12.

In the present invention, the detection of the current features of the shell 11 and the door 12 by the photosensitive coupling element 50 must be compared with a standard product of the FOUP 10 to identify whether the FOUP 10 being inspected on the production line has defects.

Since the standard FOUP 10 itself has a plurality of standard features S in shape and structure, and the plurality of standard features S should include a plurality of internal standard features S1 and a plurality of external standard features S2 formed on the shell 11 and the door 12. Further, the plurality of internal standard features S1 construct a plurality of standard images of the inner wall surfaces of the shell 11 and the door 12 (including the shape and structural outline), and the plurality of external standard features S2 construct the shape and structural outline of the plurality of outer wall surfaces of the shell 11 and the door 12. In other words, the plurality of internal standard features S1 and the plurality of external standard features S2 can jointly construct a complete three-dimensional image of the inner and outer wall surfaces of the FOUP 10.

Correspondingly, the current features N of the FOUP 10 on the production line detected by the photosensitive coupling element 50 according to the present invention should also include a plurality of internal current features N1 and a plurality of external current features N2 presented on the inner and outer wall surfaces of the shell 11 and the door 12 being inspected on the production line. The plurality of internal current features N1 should be compared with the plurality of internal standard features S1 to determine whether there are defects in the shape and outline of the inner wall surfaces of the inspected shell 11 and door 12. Furthermore, the plurality of external current features N2 should be compared with the plurality of external standard features S2 to determine whether there are defects in the shape and outline of the outer wall surfaces of the inspected shell 11 and door 12.

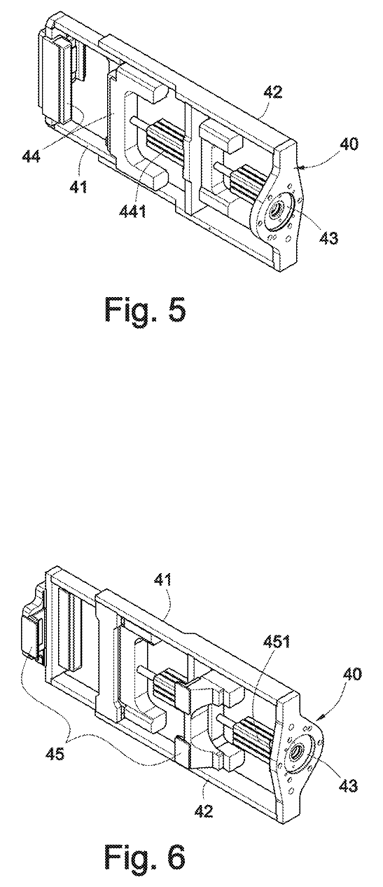

Please refer to FIGS. 5 and 6 together. FIG. 5 discloses a perspective view of the gripper 40 attached to the robot 27 shown in FIG. 2 from a first angle, illustrating that the gripper 40 can be formed as a frame body having two end surfaces 41 and 42. The two end surfaces 41 and 42 can be implemented as mutually parallel corresponding forms. One side of the gripper 40 has a connecting base 43 for locking connection with the automated tool 30. One end surface 41 of the gripper 40 is provided with a first clamping device 44 capable of gripping the flange 113 on the shell 11. FIG. 6 discloses that the other end surface 42 of the gripper 40 is provided with another second clamping device 45 capable of gripping the opposite side edges of the door 12. The first clamping device 44 and the second clamping device 45 are respectively driven by drivers 441 and 451, providing them with the ability to open and close their gripping jaws.

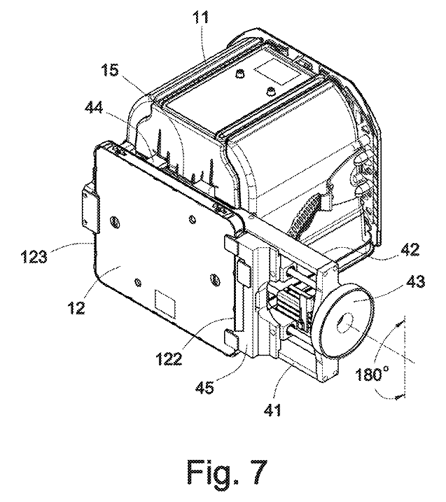

Additionally, as shown in FIG. 7, it discloses that the first clamping device 44 on the end surface 41 and the second clamping device 45 on the end surface 42 of the gripper 40 can respectively grip the flange 113 on the shell 11 and the opposite side edges 122 and 123 of the door 12 by the gripper 40 performing a 180-degree flipping action.

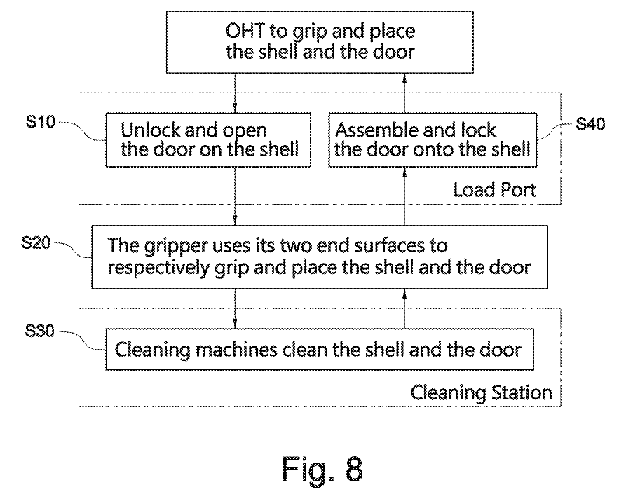

Based on the above operating device, the present invention can implement an operating method for cleaning the FOUP 10. Please refer to FIG. 8, which discloses the operating process for cleaning the FOUP according to the present invention. First, before executing the inventive operating method, it is necessary to rely on an OHT to transport the FOUP 10 to be cleaned on the production line to the input port 211 (or load port 21) for placement (as shown in FIG. 3). Subsequently, the following Step S10 to Step S40 are executed:

### Step S10: Unlock and open the door on the shell

This step takes the configuration shown in FIG. 3 as an example to illustrate the unlocking and opening of the door 12 on the shell 11 by means of the door opener 31 (or unlocker 30) arranged on the end side of the table surface 210 of the input port 211. Specifically, for the FOUP 10 transported by the OHT to the input port 211 (or load port 21) and placed there (as shown in FIG. 3), the outer wall surface of the door 12 is exposed facing the base 32 of the door opener 31. In the example shown in FIG. 3, the base 32 of the door opener 31 is placed horizontally, so that the base surface 320 faces upward, exposing the pair of keys 33.

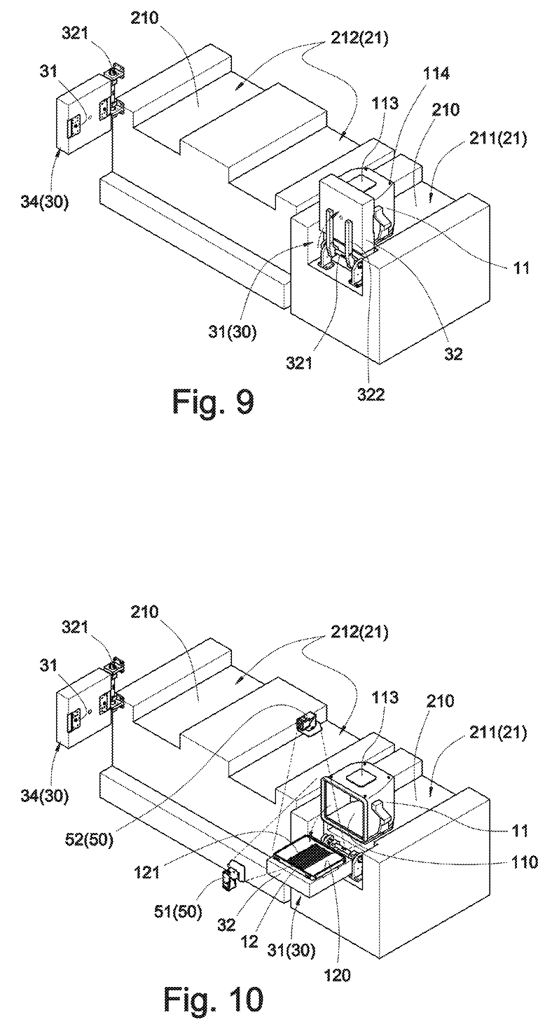

Please refer to FIG. 9, which discloses that the horizontally placed base 32 of the door opener 31 described in FIG. 3 swings toward the door 12 via the arm portion 322 and the pivot portion 321, so that the base surface 320 shown in FIG. 3 covers the outer wall surface of the door 12, and the pair of keys 33 are inserted into the pair of locking holes of the door 12 to unlock the door 12.

Please refer to FIG. 10, which discloses that the base 32 in FIG. 9 holds the door 12 by means of the pair of keys 33 shown in FIG. 3, so that the door 12 follows the base 32 as it swings back to its original horizontal position, thereby detaching from the shell 11, and exposing the inner wall surface of the door 12, which is equipped with the sealing gasket 120 and the row-shaped guide ribs 121, facing upward, completing the opening of the door 12 on the shell 11.

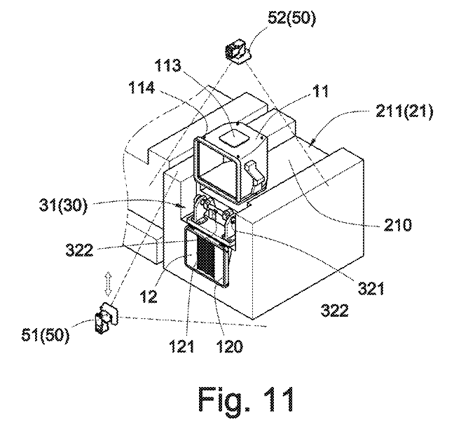

Please refer to FIG. 11, which discloses that the base 32 of the door opener 31 (or unlocker 30) can drive the door 12 via the arm portion 322 and the pivot portion 321 to swing to a vertical state (different from the horizontal state shown in FIG. 7), so that the inner wall surface of the door 12, equipped with the sealing gasket 120 and the row-shaped guide ribs 121, can be exposed outward, thereby completing the opening of the door 12 on the shell 11.

### Step S20: The gripper uses its two end surfaces to respectively grip and place the shell and the door

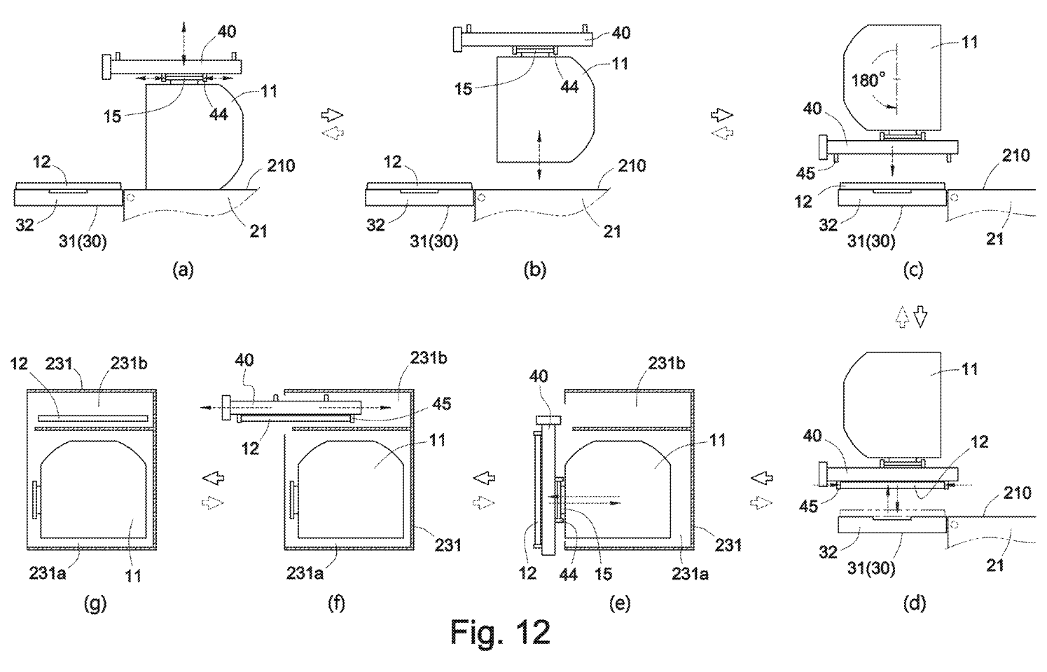

Please refer to FIGS. 12(a) and 12(g), which sequentially disclose the execution content of this step. The action of the gripper 40 is indicated by dotted solid arrows, and the sequence from (a) to (g) is indicated by solid hollow arrows.

First, as shown in FIG. 12(a), after the FOUP 10 is unlocked by the door opener 31 (or unlocker 30) into the separated shell 11 and door 12 as shown in FIGS. 10 or 11, the robot 27 shown in FIG. 2 can drive the gripper 40 to move to the input port 211 (or load port 21), and use the first clamping device 44 to grip the flange 113 on the shell 11. Next, as shown in FIG. 12(b), the gripper 40 lifts the shell 11 away from the load port 21 using the first clamping device 44. Subsequently, taking the door 12 in a horizontal placed state as shown in FIG. 10 as an example, as shown in FIG. 12(c), the gripper flips 180 degrees, driving the second clamping device 45 on the gripper 40 to face downward corresponding to the door 12 on the base 32. Next, as shown in FIG. 12(d), the gripper 40 immediately moves down and uses the second clamping device 45 to grip the opposite side edges 122 and 123 of the door 12, so that the two end surfaces of the gripper 40 can respectively grip the shell 11 and the door 12, thereby simultaneously transporting the shell 11 and the door 12 from the load port 21 to the plurality of cleaning stations [as shown in FIGS. 12(e)-12(g)].

### Step S30: Cleaning machines clean the shell and the door

Please refer to FIGS. 2 and 12(e) together. FIG. 2 discloses that the plurality of cleaning machines 23 actually include at least one cleaning machine 231 for wet cleaning purposes as shown in FIG. 12(e). The gripper 40 can place the shell 11 and the door 12 in the same cleaning machine 231. FIG. 12(e) further discloses that the at least one cleaning machine 231 can actually be distinguished into a shell cleaning machine 231a dedicated to cleaning the shell 11 and a door cleaning machine 231b dedicated to cleaning the door 12. When the gripper 40 simultaneously transports the shell 11 and the door 12 to the cleaning machine 231, it can first move to the shell cleaning machine 231a and release the first clamping device 44 to place the shell 11 into the shell cleaning machine 231a [as shown in FIG. 12(e)], and then move to the door cleaning machine 231b and release the second clamping device 45 to place the door 12 into the door cleaning machine 231b [as shown in FIG. 12(f)], so that the shell 11 and the door 12 can undergo wet cleaning in the cleaning machine 231 [as shown in FIG. 12(g)]. The robot 27 can drive the gripper 40 to rotate by a necessary angle to facilitate the gripper 40 placing the shell 11 and the door 12 one by one into the cleaning machine 231. The shell cleaning machine 231a and the door cleaning machine 231b can be arranged in stacked or separate tank configurations.

Further, the plurality of cleaning machines 23 shown in FIG. 2 also include at least one vacuum dryer 232. When there are multiple vacuum dryers 232, they can similarly be arranged in a stacked or separate configuration around the robot 27. The method by which the gripper 40 transports and places the shell 11 and door 12 into the vacuum dryer can be analogous to the method by which the gripper 40 transports and places the shell 11 and door 12 into the cleaning machine 231. Further, after the shell 11 and door 12 are cleaned in the cleaning machine 231, the gripper 40 can sequentially grip the shell 11 and door 12 from the cleaning machine 231 and move them to the vacuum dryer 232 shown in FIG. 2 for placement, and so on. This allows the gripper 40 to successively place and grip the shell 11 and door 12 among the plurality of cleaning machines 23, enabling the shell 11 and door 12 to complete the established cleaning process.

### Step S40: Assemble and lock the door onto the shell

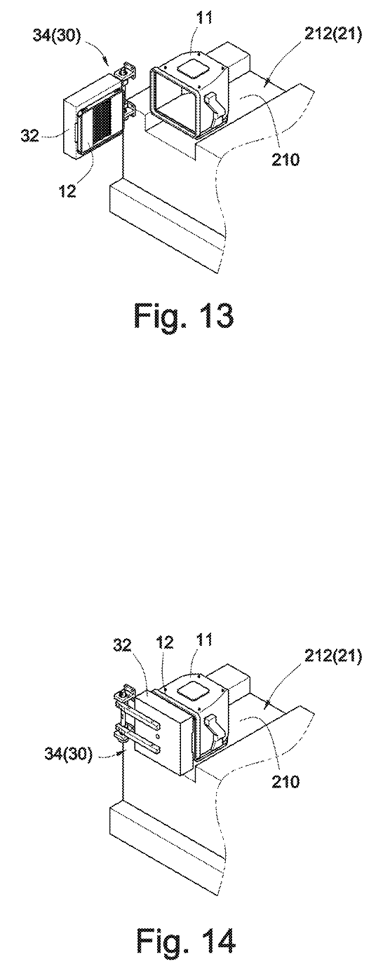

Please refer back to FIGS. 12(f)-12(a), which discloses that after the shell 11 and door 12 complete the cleaning process of Step S30, the gripper 40 can use the same method as in Step S20 with the first clamping device 44 and the second clamping device 45 to sequentially grip the shell 11 and door 12 from the cleaning machines 23, and transport them to the output port 212 shown in FIG. 3. Please further refer to FIG. 13, which discloses that the gripper 40 places the shell 11 onto the table surface 210 of the output port 212, and places the door 12 onto the base 32 of the door closer 34 (or unlocker 30). Subsequently, please refer to FIG. 14, which discloses that the door 12 is driven by the base 32 to be assembled onto the opening 110 of the shell 11. The door closer 34 (or unlocker 30) then uses the pair of keys to lock the door 12 and the shell 11 together, forming the FOUP 10 after the completion of the cleaning process.

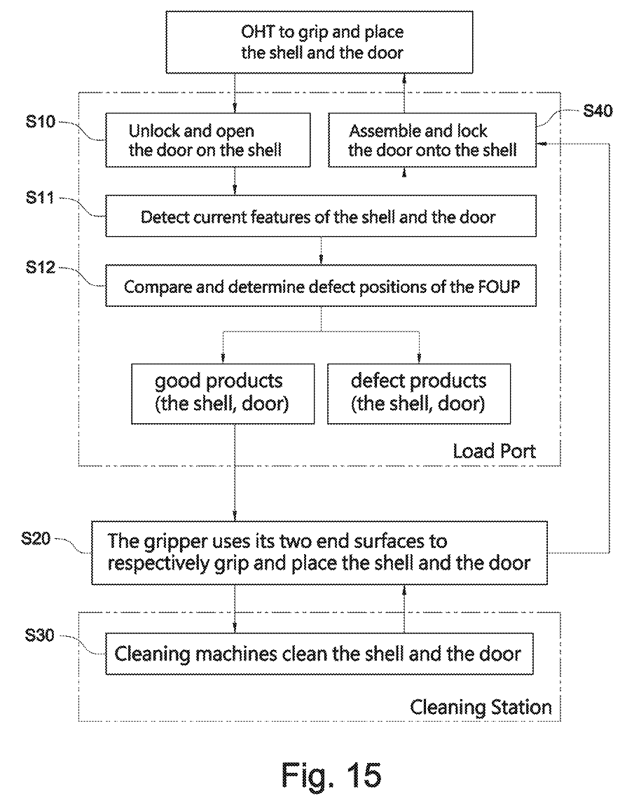

In addition to the above operating method, the present invention also includes an additional FOUP defect inspection process after executing the above Step S10 (unlocking and opening the door 12 on the shell 11) and before executing the above Step S20 (gripper 40 gripping the shell 11 and door 12). This defect inspection process includes executing a Step S11 and a Step S12 (as shown in FIG. 15). Wherein:

### Step S11: Detect current features of the shell and the door

As shown in FIGS. 10 and 15, this Step S11 can utilize one or more photosensitive coupling elements 50 suspended around the table surface 210 of the input port 211 (or load port 21) to detect the current features of the shell 11 and the door 12. Specifically, when the load port 21 is divided into the input port 211 and the output port 212, the photosensitive coupling element 50 is suspended over the input port 211. When the load port 21 simultaneously serves both input and output functions, the photosensitive coupling element 50 is suspended over the load port 21, used to detect the current features of the shell 11 and the door 12 before executing the cleaning process, thereby determining the quality of the shell 11 and the door 12.

In the example of FIG. 10, when the photosensitive coupling element 50 includes the first photosensitive coupling element 51 and the second photosensitive coupling element 52, the fixed first photosensitive coupling element 51 can be positioned corresponding to the opening 110 of the shell 11 to capture an image of the inner wall surface of the shell 11 having the internal guide ribs 112. The second photosensitive coupling element 52, which can move linearly in the horizontal direction, can be moved to a position corresponding to the inner wall surface of the door 12, which is equipped with the sealing gasket 120 and the row-shaped guide ribs 121, to capture an image. These images together serve as the internal current features N1 of the inspected FOUP 10 (composed of current images of the inner end surfaces of the FOUP). At the same time, the second photosensitive coupling element 52 can also be moved to a position corresponding to the top surface area of the shell 11 including the flange 113 to capture an image, serving as the external current features N2 of the inspected FOUP 10.

Further, in the example of FIG. 10, besides being implemented in a fixed manner, the first photosensitive coupling element 51 can also be implemented to move linearly in the horizontal direction. The internal current features N1 of the FOUP 10 may also include an image captured by the first photosensitive coupling element 51 corresponding to the edge position of the door 12, capturing the side wall of the door 12 combined with the side of the sealing gasket 120, used to determine whether the sealing gasket 120 is damaged or detached. Also, in the example shown in FIG. 7, the external current features N2 may also include, in the state of FIG. 3, an image of the outer wall surface of the door 12 having the pair of locking holes captured by the first photosensitive coupling element 51, which together with the image of the top surface area of the shell 11 including the flange 113, serve as the external current features N2 of the inspected FOUP 10.

In the example of FIG. 11, when the photosensitive coupling element 50 includes the first photosensitive coupling element 51 and the second photosensitive coupling element 52, the first photosensitive coupling element 51 can sequentially correspond to the position of the opening 110 of the shell 11, capturing an image of the inner wall surface of the shell 11 having the internal guide ribs 112 and an image of the inner wall surface of the door 12 equipped with the sealing gasket 120 and the row-shaped guide ribs 121. These images together serve as the internal current features N1 of the inspected FOUP 10. At the same time, the movable or fixed second photosensitive coupling element 52 can capture an image corresponding to the top surface area of the shell 11 including the flange 113, serving as the external current features N2 of the inspected FOUP 10. Similarly, in the example shown in FIG. 8, the external current features N2 may also include, in the state of FIG. 3, an image of the outer wall surface of the door 12 having the pair of locking holes captured by the first photosensitive coupling element 51, which, together with the image of the top surface area of the shell 11 including the flange 113 and the screws 114, serve as the external current features N2 of the inspected FOUP 10.

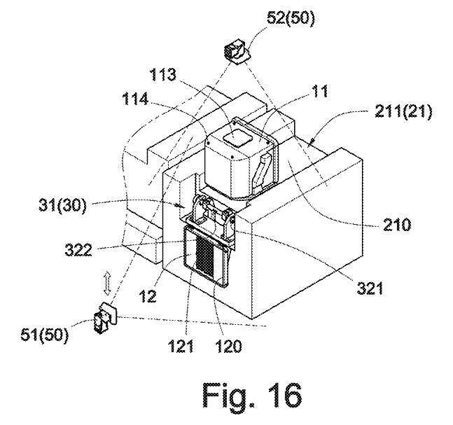

Please refer to FIG. 16, which discloses that the shell 11 placed on the table surface 210 of the input port 211 with the door 12 already opened (as in FIG. 8) can be rotated 180 degrees by means of an additional rotary table (not shown in the figure) configured on the table surface 210, or by the robot 27 within the cleaning area station 20. This allows the first photosensitive coupling element 51 to capture an image of the rear wall surface of the shell 11, serving as a part of the external current features N2 of the inspected FOUP 10, which also falls within the scope of additional applications of the present invention.

In a possible alternative implementation, before unlocking the FOUP 10, the present invention can first detect the plurality of external current features N2 of the shell 11 and the door 12 according to the above method, and compare the differences between the external current features N2 and the external standard features S2. Subsequently, the door 12 on the shell 11 is unlocked and opened, the plurality of internal current features N1 of the shell 11 and the door 12 are detected, and the differences between the internal current features N1 and the internal standard features S1 are compared.

### Step S12: Compare and determine defect positions of the FOUP

This step uses a control unit (which can be made of an MCU, not shown in the figure) configured in the device body. The control unit has internally stored standard features S (including internal standard features S1 and external standard features S2) of the shell 11 and the door 12. The control unit receives the current features N (including internal current features N1 and external current features N2) detected in the above Step S20, and then compares whether there are differences in the image features between the standard features S and the current features N. If there is an error in the image features that exceeds a predetermined allowable range, the position where the error exists is determined to be a defect position of the FOUP 10. It is also determined whether the defect position is located on the inner wall surface or/and the outer wall surface of the shell 11 or/and the door 12. Thereby, the shells 11 and doors 12 that are good products and those that are defective are determined and summarized. This completes the FOUP defect inspection process of the present invention, so that when subsequently executing said Step S20, the gripper 40 can transport the shells 11 and doors 12 that are good products for the cleaning process.

Since the execution processes of the above Step S10, Step S11 to Step S20 are all performed at the load port 21 (or input port 211), and the robot 27 within the cleaning area station 20 is only responsible for transporting the already unlocked and inspected shells 11 and doors 12 successively into and out of the cleaning machines 22, 23, 24 for wet cleaning and vacuum drying cleaning processes. Therefore, the execution process of the present invention can significantly reduce the operation time for the robot 27 within the cleaning area station 20 to transport the shells 11 and doors 12 for sequential cleaning.

Further, shells 11 or doors 12 identified as defective through inspection at the load port 21 (or input port 211) can be directly removed by an OHT or other automated equipment, eliminating defective products from the production line. This prevents the robot 27 within the cleaning area station 20 from picking up already defective shells 11 or doors 12 for cleaning, thus greatly improving the operational efficiency of cleaning FOUPs while also detecting defective products.

In a possible alternative implementation, the execution process of the above Step S11 to Step S12 can also be changed to be performed at the output port 212. This includes, before the door closer 34 (or unlocker 30) drives the door 12 to lock onto the shell 11, first having said photosensitive coupling element 50 (including the first photosensitive coupling element 51 and the second photosensitive coupling element 52) execute Step S11, i.e., detecting the current features N (including internal current features N1 and external current features N2) of the shell 11 and the door 12 after cleaning. Subsequently, the control unit executes said Step S12, i.e., comparing and determining the defect positions of the FOUP, to complete the FOUP defect inspection process of the present invention. Only then does the door closer 34 (or unlocker 30) drive the door 12 to lock onto the shell 11 (as in FIG. 11), completing the assembly of the cleaned FOUP 10. Accordingly, the OHT or other automated equipment can automatically identify whether the FOUP 10 on the output port 212 is a good product or a defective one, and then transport it to an appropriate location respectively, allowing the FOUP 10 to leave the cleaning area station 20.

Although the invention has been explained in relation to its preferred embodiment, it is to be understood that many other possible modifications and variations can be made without departing from the spirit and scope of the invention as hereinafter claimed.

1. An operating method for cleaning a FOUP, applied in a cleaning area station for the FOUP, the cleaning area station comprising at least one load port for placing the FOUP, a plurality of cleaning machines for cleaning the FOUP, and a robot for transporting the FOUP between the at least one load port and the plurality of cleaning machines; the at least one load port is provided with an unlocker for unlocking the FOUP into a shell and a door, and for locking the shell and the door together to form the FOUP; the robot has a gripper attached thereto, the gripper having a first clamping device and a second clamping device respectively disposed on two opposite end surfaces thereof;
the operating method comprises: unlocking and opening the door on the shell by means of the unlocker on the at least one load port; then, gripping the shell from the at least one load port by means of the first clamping device of the gripper, and gripping the door from the at least one load port by means of the second clamping device of the gripper; enabling the gripper to simultaneously transport the shell and the door from the at least one load port and place them one by one into the plurality of cleaning machines for cleaning; and sequentially gripping the shell and the door cleaned by the plurality of cleaning machines, thereby enabling the gripper to simultaneously transport the shell and the door from the plurality of cleaning machines to the at least one load port; and using the unlocker to assemble the door onto the shell and lock them together to form the cleaned FOUP.

2. The operating method for cleaning a FOUP defined in claim 1, wherein the unlocker uses one of a swinging motion or a linear motion to open the door on the shell.

3. The operating method for cleaning a FOUP defined in claim 1, wherein the robot drives the gripper to reciprocally flip by a specific angle, enabling the first clamping device to grip and release the shell, and the second clamping device to grip and release the door.

4. The operating method for cleaning a FOUP defined in claim 3, wherein the two opposite end surfaces of the gripper provided with the first clamping device and the second clamping device are parallel and correspond to each other, and the specific angle is 180 degrees.

5. The operating method for cleaning a FOUP defined in claim 3, wherein the first clamping device grips a flange on the shell, and the second clamping device grips both side edges of the door.

6. The operating method for cleaning a FOUP defined in claim 1, wherein at least one photosensitive coupling element is provided around the at least one load port, and the operating method further comprises, after the unlocker unlocks and opens the door on the shell, and before the gripper grips the shell and the door, inspecting the quality of the shell and the door by means of the at least one photosensitive coupling element at the at least one load port.

7. The operating method for cleaning a FOUP defined in claim 6, wherein the shell and the door have a plurality of internal standard features according to product specifications, the at least one photosensitive coupling element is used to detect a plurality of internal current features of the shell and the door, and the operating method further comprises comparing differences between the internal current features and the internal standard features to determine defect locations on the shell and the door, and selecting good shells and doors, allowing the gripper to grip and transport the unlocked good shell and good door from the at least one load port to the plurality of cleaning machines for cleaning.

8. The operating method for cleaning a FOUP defined in claim 6, wherein the internal standard features are constituted by at least one standard image of an inner end surface of the shell and the door, and the internal current features are respectively constituted by at least one current image of an inner end surface of the shell and the door.

9. The operating method for cleaning a FOUP defined in claim 7, wherein the shell and the door also have a plurality of external standard features according to product specifications, and the operating method further comprises, before unlocking and opening the door on the shell, detecting a plurality of external current features of the shell and the door, and comparing differences between the external current features and the external standard features.

10. The operating method for cleaning a FOUP defined in claim 9, wherein the photosensitive coupling element detects the external current features and the internal current features using at least one of a fixed method and a moving method.

11. The operating method for cleaning a FOUP defined in claim 9, wherein the external standard features are constituted by at least one standard image of an outer end surface of the shell and the door, and the external current features are constituted by at least one current image of an outer end surface of the shell and the door.

12. The operating method for cleaning a FOUP defined in claim 1, wherein the at least one load port comprises at least one input port and at least one output port, the operation of unlocking the FOUP into the shell and the door is performed at the at least one input port, and the operation of locking the shell and the door together to form the FOUP is performed at the at least one output port.

13. The operating method for cleaning a FOUP defined in claim 12, wherein the at least one input port unlocks the door from the shell by means of a door opener, the at least one output port locks the door onto the shell by means of a door closer, and the door closer uses one of a swinging motion or a linear motion to close the door on the shell.

14. An operating device for cleaning a FOUP, configured in a cleaning area station for the FOUP, for unlocking the FOUP into a shell and a door, transporting the shell and the door for cleaning, and locking the cleaned shell and door together to form the FOUP; the cleaning area station comprising at least one load port for placing the FOUP, a plurality of cleaning machines for cleaning the FOUP, and a robot for transporting the FOUP between the at least one load port and the plurality of cleaning machines, the at least one load port having a table surface for placing the FOUP; the operating device comprising:
an unlocker, having a pair of keys capable of inserting into a pair of locking holes of the door, configured to unlock and open the door on the shell, and to lock the shell and the door together to form the FOUP; and
a gripper, attached to the robot, the gripper having a first clamping device and a second clamping device respectively disposed on two opposite end surfaces thereof, the first clamping device being configured to grip and release the shell between the at least one load port and the plurality of cleaning stations, and the second clamping device being configured to grip and release the door between the at least one load port and the plurality of cleaning stations;
wherein, the unlocker is disposed on one end side of the at least one load port adjacent to the table surface, and the robot drives the gripper to reciprocally flip by a specific angle, enabling the first clamping device to grip and release the shell, and the second clamping device to grip and release the door.

15. The operating device for cleaning a FOUP defined in claim 14, wherein the unlocker has a base capable of holding the door, the pair of keys protrudes outward from a base surface of the base, and the base has a pivot portion, the base being pivotally connected to an end side of the table surface of the at least one load port via the pivot portion, such that the base can insert the pair of keys into the pair of locking holes of the door in a swinging motion, unlocking and opening the door on the shell.

16. The operating device for cleaning a FOUP defined in claim 14, wherein the unlocker has a base capable of holding the door, the pair of keys protrudes outward from a base surface of the base, and the base is slidably assembled to an end side of the table surface of the at least one load port via a linear slide rail, such that the base can insert the pair of keys into the pair of locking holes of the door in a linear movement, unlocking and opening the door on the shell.

17. The operating device for cleaning a FOUP defined in claim 14, further comprising at least one photosensitive coupling element suspended around the table surface of the at least one load port, configured to detect a plurality of current features of the unlocked shell and the door at the at least one load port.

18. The operating device for cleaning a FOUP defined in claim 17, wherein the photosensitive coupling element is suspended around the table surface of the at least one load port using at least one of a fixed method and a moving method.

19. The operating device for cleaning a FOUP defined in claim 14, wherein the at least one load port comprises at least one input port and at least one output port for placing the FOUP, the unlocker comprises a door opener installed on an end side of the table surface of the input port, and a door closer installed on an end side of the table surface of the output port, the door opener being configured to unlock and open the door on the shell, and the door closer being configured to assemble and lock the door onto the shell to form the FOUP.
